(19) United States
(12) Patent Application Publication
(10) Pub. No.: US 2023/0420919 A1
(43) Pub. Date: Dec. 28, 2023

(54) Radiation-Emitting Laser Diode, Method for Choosing Refractive Indices of a Waveguide Layer Sequence for a Radiation-Emitting Laser Diode and Method for Producing a Radiation-Emitting Laser Diode

(71) Applicant: ams-OSRAM International GmbH, Regensburg (DE)

(72) Inventors: Christian Lauer, Pettendorf (DE); Martin Mueller, Bernhardswald (DE); Michael Furitsch, Ascha (DE); Harald König, Bernhardswald (DE)

(21) Appl. No.: 18/253,185

(22) PCT Filed: Dec. 3, 2020
(86) PCT No.: PCT/EP2020/084441

§ 371 Date: May 16, 2023

(51) Int. Cl. H01S 5/20; H01S 5/34

(52) U.S. Cl. CPC H01S 5/2031; H01S 5/3404; H01S 2301/14

(57) ABSTRACT

In an embodiment a radiation-emitting laser diode includes a waveguide layer sequence having an active region configured to generate electromagnetic radiation with a preferred polarization direction, a first waveguide layer of a first doping type and a second waveguide layer of a second doping type, wherein the active region is arranged between the first waveguide layer and the second waveguide layer, wherein refractive indices of the waveguide layer sequence form a first effective refractive index for a transverse electric (TE) mode with its electric field oscillating in a first transverse direction and a second effective refractive index for a transverse magnetic (TM) mode with its electric field oscillating in a second transverse direction, and wherein an effective refractive index difference of the first effective refractive index and the second effective refractive index is at least 4·10⁻⁴.

### CROSS-REFERENCE TO RELATED APPLICATIONS

This application is a national phase entry of PCT Application No. PCT/EP2020/084441, filed on Dec. 3, 2020, which application is hereby incorporated herein by reference.

### TECHNICAL FIELD

A radiation-emitting laser diode is provided. Furthermore, a method for choosing refractive indices of a waveguide layer sequence for a radiation-emitting laser diode and a method for producing such a radiation-emitting laser diode are provided.

### SUMMARY

Embodiments provide a radiation-emitting laser diode having an improved polarization purity. Further embodiments provide a method for choosing refractive indices of a waveguide layer sequence for such a radiation-emitting laser diode and a method for producing such a radiation-emitting laser diode.

The radiation-emitting laser diode is configured, for example, to emit electromagnetic laser radiation during operation such as monochromatic and coherent laser light. The electromagnetic laser radiation is, for example, in the frequency range from infrared, IR, radiation to ultra violet, UV, radiation.

According to at least one embodiment, the radiation-emitting laser diode comprises a waveguide layer sequence.

The waveguide layer sequence is, for example, formed of a III-V compound semiconductor. The III-V compound semiconductor is, for example, an arsenide compound semiconductor, a nitride compound semiconductor or a phosphide compound semiconductor.

The waveguide layer sequence has, for example, a main plane of extension. A vertical direction extends perpendicular to the main plane of extension and lateral directions extend parallel to the main plane of extension. Furthermore, the waveguide layer sequence has, for example, a main extension direction aligned parallel to one of the lateral directions.

For example, the waveguide layer sequence is produced by an epitaxial growth process. This is to say that the layers of the waveguide layer sequence are epitaxially grown on top of one another in vertical direction.

According to at least one embodiment of the radiation-emitting laser diode, the waveguide layer sequence comprises an active region configured to generate electromagnetic radiation of a preferred polarization direction. For example, the electromagnetic radiation generated in the active region is emitted as electromagnetic laser radiation having a very high coherence length, a very narrow emission spectrum and/or a high degree of polarization.

The polarization direction is defined as a spatial oscillation direction of an electric field of electromagnetic radiation. For example, for generating electromagnetic radiation, the active region can comprise a double heterostructure, a single quantum well structure or a multiple quantum well structure. Depending on the inherent strain of the active region due to a pre-set material composition, the generated electromagnetic radiation is predominantly polarized in the vertical direction for a compressively strained active region and predominantly polarized in one of the lateral directions for tensile strained active regions.

According to at least one embodiment of the radiation-emitting laser diode, the waveguide layer sequence comprises a first waveguide layer of a first doping type and a second waveguide layer of a second doping type.

For example, the first doping type is different from the second doping type. For example, the first waveguide layer is n-doped. Furthermore, the second waveguide layer is, for example, p-doped. In this case, the first doping type is of an n-type and the second doping type is of a p-type.

According to at least one embodiment of the radiation-emitting laser diode, the active region is arranged between the first waveguide layer and the second waveguide layer. For example, the first waveguide layer, the active region and the second waveguide layer are stacked above one another in vertical direction, in particular in the order indicated. For example, the active region is directly adjacent to the first waveguide layer and/or the second waveguide layer.

According to at least one embodiment of the radiation-emitting laser diode, refractive indices of the waveguide layer sequence form a first effective refractive index for a transverse electric, TE, mode with its electrical field oscillating in a first transverse direction and a second effective refractive index for a transverse magnetic, TM, mode with its electrical field oscillating in a second transverse direction.

For example, the first transverse direction and the second transverse direction are aligned within a plane being perpendicular to the main extension direction. Exemplary, the main extension direction is parallel to a propagation direction of the electromagnetic laser light. Furthermore, the first transverse direction is aligned perpendicular to the second transverse direction.

The TE mode and the TM mode are formed of an electromagnetic field of the electromagnetic radiation within the waveguide layer sequence in the plane perpendicular to the propagation direction of the electromagnetic radiation. Exemplarily, the TE mode and the TM mode occur due to a confinement of the electromagnetic radiation within the waveguide layer sequence. In particular, the TE mode and the TM mode occur due to different boundary conditions between adjacent layers of the waveguide layer sequence.

Exemplarily, since the waveguide layer sequence is a layered structure and since the electric field of the TE mode oscillates along the first transverse direction and the electric field of the TM mode oscillates along the second transverse direction, both modes have different effective refractive indices.

Further, since the waveguide layer sequence is a layered structure and since the TE and TM modes exemplarily experience different Fresnel reflection coefficients at the interfaces between the layers, the according Eigenvalue problems and the resulting effective refractive indices differ for the TE mode and the TM mode. For example, the TE mode has the first effective refractive index of the waveguide layer sequence and the TM mode has the second effective refractive index of the waveguide layer sequence.

For example, the first waveguide layer and/or the second waveguide layer consists of a single layer or a plurality of sublayers.

According to at least one embodiment of the radiation-emitting laser diode, an effective refractive index difference of the first effective refractive index and the second effective refractive index is at least 4·10⁻⁴. For example, a polarization intensity ratio of the TE mode and the TM mode is dependent on the effective refractive index difference.

For example, the effective refractive index difference is at least 5·10⁻⁴, in particular at least 7·10⁻⁴, 1·10⁻³ or 1·10⁻².

The polarization intensity ratio is defined for the TE mode by the equation

$${PR}_{TE} = \frac{{I}_{TE}}{{I}_{TE} + {I}_{TM}} ,$$

wherein I_{TE} is the intensity of the TE mode, in particular the TE ground mode and I_{TM} is the intensity of the TM mode, in particular the TM ground mode. The polarization intensity ratio is defined for the TM mode by the equation

$${PR}_{TM} = \frac{{I}_{TM}}{{I}_{TE} + {I}_{TM}} = 1 - {PR}_{TE} .$$

For example, if the effective refractive index difference is 4·10⁻⁴, the polarization intensity is at least 90%. For example, if the effective refractive index difference is at least 5·10⁻⁴, the polarization intensity ratio is at least 93%. For example, if the effective refractive index difference is at least 7·10⁻⁴, the polarization intensity ratio is at least 96% and if the effective refractive index difference is at least 1·10⁻³, the polarization intensity ratio is at least 97%. The relations of the effective refractive index differences and the associated polarization intensity ratios listed here are, for example, indicated for a radiation-emitting laser diode being mounted in order to operate the radiation-emitting laser diode properly.

Furthermore, the effective refractive index difference is for example at most 2, in particular at most 1·10⁻² or at most 5·10⁻³.

According to at least one embodiment, the radiation-emitting laser diode comprises a waveguide layer sequence comprising an active region configured to generate electromagnetic radiation, a first waveguide layer of a first doping type and a second waveguide layer of a second doping type. The active region is arranged between the first waveguide layer and the second waveguide layer, and the refractive indices of the waveguide layer sequence form a first effective refractive index for a transverse electric mode with its electric field oscillating in a first transverse direction and a second effective refractive index for a transverse magnetic mode with its electric field oscillating in a second transverse direction. An effective refractive index difference of the first effective refractive index and the second refractive index is at least 4·10⁻⁴.

One idea of the radiation-emitting laser diode described herein is, inter alia, to have a mismatch of the first effective index associated with the TE mode and the second effective index associated with the TM mode being larger than 4·10⁻⁴. With such a difference a comparatively high polarization purity of the electromagnetic radiation emitted by the radiation-emitting laser diode can be achieved.

According to at least one embodiment of the radiation-emitting laser diode, the refractive indices of the active region, the first waveguide layer and the second waveguide layer differ from one another. For example, a refractive index of the active region is larger than a refractive index of the first waveguide layer and a refractive index of the second waveguide layer. Furthermore, the refractive index of the first waveguide layer is smaller than the refractive index of the second waveguide layer or vice versa.

According to at least one embodiment of the radiation-emitting laser diode, thicknesses of the active region, the first waveguide layer and the second waveguide layer differ from one another. The thicknesses of the active region, the first waveguide layer and the second waveguide layer are each defined by an extent of the corresponding layer in vertical direction.

Exemplarily, since the TE mode and the TM mode experience different Fresnel reflection coefficients at the interfaces between the layers of the waveguide layer sequence, the effective indices of the TE mode and the TM mode are also dependent on the thicknesses of the layers of the waveguide layer sequence.

For example, a thickness of the active region is smaller than a thickness of the first waveguide layer and a thickness of the second waveguide layer.

According to at least one embodiment of the radiation-emitting laser diode, a length of the waveguide layer sequence is at least 500 μm and at most 6 mm. In particular, the length of the waveguide layer sequence is at least 600 μm and at most 5 mm. For example the length of the waveguide layer sequence is defined by an extent of the waveguide layer in the main extension direction.

According to at least one embodiment of the radiation-emitting laser diode, a first cladding layer of the first doping type is arranged on the waveguide layer sequence of a first main surface. Exemplarily, the first main surface faces away from the active region. In particular, wave guide properties of the electromagnetic radiation also depend on the first cladding layer.

According to at least one embodiment of the radiation-emitting laser diode, a second cladding layer of the second doping type is arranged in the waveguide layer sequence on the second main surface. Exemplarily, the second main surface faces away from the active region. In particular, wave guide properties of the electromagnetic radiation also depend on the second cladding layer.

For example, the refractive indices of the waveguide layer sequence and the refractive indices of the first cladding layer and the second cladding layer as well as corresponding layer thicknesses of the layers form the first effective refractive index and the second effective refractive index of the TE mode and the TM mode. Exemplarily, all layers, which have an overlap with the TE mode and the TM mode, have to be considered for the first effective refractive index and the second effective refractive index.

The first cladding layer and/or the second cladding layer comprise, for example, a plurality of further sublayers. Each sublayer can have a different doping concentration and/or doping type.

According to at least one embodiment of the radiation-emitting laser diode, a metallic contact layer is arranged on the second cladding layer in an electrically and thermally conductive manner. For example, the metallic contact layer is in direct contact to the second cladding layer. For example, the metallic contact layer is formed as a heatsink of the radiation-emitting laser diode. Further, the metallic contact layer is configured to attach the radiation-emitting laser diode on a carrier.

The metallic contact layer comprises or consists of, for example, a metal or a combination of metals, such as Ti, Pt, Pd, Cr, Al, Ni, Ge, Rh, Si, Cu, Ag, W, TiW, TiWN, and Au.

If the radiation-emitting laser diode has an effective refraction index difference being less than 4·10⁻⁴ and if the radiation-emitting laser diode comprises the metallic contact layer for mounting the radiation-emitting laser diode on the carrier, the polarization intensity ratio is reduced in comparison to a radiation-emitting laser diode, which does not have the metallic contact layer. For example, the metallic contact layer induces strain to the waveguide layer sequence. In particular, strain being caused by e.g. a shear force, is induced in the waveguide layer sequence when mounting the radiation-emitting laser diode with the metallic contact layer to, e.g. the carrier. The induced strain leads to a reduction of the polarization intensity ratio due to double refraction invoked by an opto-elastic process under the strain. In this case, the polarization intensity ratio can be less than 93%, in particular less than 88%.

However, since the radiation-emitting laser diode advantageously has an effective refraction index difference being higher than 4·10⁻⁴, in particular higher than 5·10⁻⁴, a particularly high polarization purity can be achieved even if the radiation-emitting laser diode is subjected to strain being caused e.g. by the shear force. Thus, even if the radiation-emitting laser diode has the metallic contact layer and is in particular mounted, which induces the strain, the median polarization intensity ratio of a sample population is advantageously higher than 90%, in particular higher than 93%.

According to at least one embodiment of the radiation-emitting laser diode, a substrate is arranged on the first cladding layer. For example, the substrate is in direct contact to the first cladding layer.

According to the radiation-emitting laser diode, the first cladding layer comprises a mode spoiler. Exemplarily, the mode spoiler increases an intensity of modes of a higher order inside the substrate and therefore an optical loss of the modes of higher order inside the substrate. At the same time, for example, an intensity of a ground mode inside the substrate is increased significantly less or even reduced as compared to the case without the mode spoiler. With the mode spoiler within the first cladding layer, the oscillation of the modes of higher order can be advantageously suppressed.

For example, the second cladding layer comprises a further mode spoiler. The mode spoiler and/or the further mode spoiler comprise, for example, Si or Ge.

Furthermore, a method for choosing refractive indices of a waveguide layer sequence for a radiation-emitting laser diode is provided. In particular, the chosen refractive indices are used for producing the waveguide layer sequence of the radiation-emitting laser diode described herein before. Thus, all features disclosed in connection with the radiation-emitting laser diode are also disclosed in connection with the method and vice versa.

According to at least one embodiment of the method, initial refractive indices for a waveguide layer sequence are provided. The waveguide layer sequence comprises an active region configured to generate electromagnetic radiation, a first waveguide layer of a first doping type and a second waveguide layer of a second doping type. For example, an initial refractive index for the active region, an initial refractive index for the first waveguide layer and an initial refractive index for the second waveguide layer are provided.

According to at least one embodiment of the method, a coupling of a transverse electric, TE, mode in a first transverse direction and a transverse magnetic, TM, mode in a second transverse direction in the waveguide layer sequence is considered as a function of the initial refractive indices.

For example, the coupling of the TE mode and the TM mode is described by two differential equations

$$\frac{{dE}_{TE}}{dz} = - j κ {E}_{TM} {e}^{- j Δ z} and \frac{{dE}_{TE}}{dz} = - j κ {E}_{TM} {e}^{- j Δ z} .$$

The energy component of the TE mode is designated by E_{TE} and the energy component of the TM mode is designated by E_{TM}. j is the imaginary number. Further, the parameter κ is a coupling parameter comprising an overlap integral of the TE mode and the TM mode taking part and an off axis element of a permittivity tensor invoked by strain via the opto-elastic effect. The parameter Δ is a propagation mismatch parameter comprising the effective refractive index difference.

Typically, E_{TE} and E_{TM} are connected to a corresponding intensity, in particular a corresponding polarization intensity, I_{TE} and I_{TM}, respectively.

Usually, the most significant interaction is, for example, between the TE ground mode and the TM ground mode, due to initial quantum well pumping of the TE ground mode and a very small overlap of the TE ground mode with all TM modes, except the TM ground mode. Thus, the TE mode and the TM mode described herein before are exemplarily formed of the TE ground mode and the TM ground mode.

According to at least one embodiment of the method, the refractive indices of the waveguide layer sequence are chosen by adjusting the initial refractive indices depending on a threshold value of the coupling. For example, materials of the waveguide layer sequence are chosen in order to decrease a coupling parameter between the TE mode and the TM mode, in particular between the TE ground mode and the TM ground mode, to be below the threshold value. This can be done by individually adjusting and/or varying, e.g., an Al content in the layers. In particular, the layers comprise AlGaAs, AlGaInN or AlGaInAsP. This is to say that an initial waveguide structure is adjusted in order to increase a propagation mismatch parameter Δ, which is proportional to the effective refractive index difference of the respective TE mode and TM mode. During the method also the electrical properties of the structure need to be considered to ensure sufficiently good carrier transport in the waveguide layer sequence.

If a coupling parameter, which represents the coupling, of the TE mode and the TM mode is below the threshold value, these materials with their respective refractive indices are chosen as the waveguide layer sequence for the radiation-emitting laser diode. In this case, the waveguide layer sequence fits for a low coupling strength between the TE mode and the TM mode.

If the coupling parameter of the TE mode and the TM mode is above the threshold value, the initial layer sequence is adjusted. In this case, the waveguide layer sequence will have to be adjusted in order to ensure a low coupling strength.

For example, the initial refractive indices are adjusted in order to minimize the coupling of the TE mode and the TM mode. This is to say that the effective refractive index difference of the first effective refractive index and the second effective refractive index are maximized, while the waveguiding properties of the waveguide layer sequence are only slightly changed.

According to at least one embodiment of the method, the coupling is dependent on an effective refractive index difference of a first effective refractive index for the TE mode and a second effective refractive index for the TM mode. For example, the parameter Δ is proportional to the effective refractive index difference. Thus, the two differential equations are dependent on the effective refractive indices. According to the differential equations, if the effective refractive index difference is decreased, for example, the coupling is increased and vice versa.

According to at least one embodiment of the method, the effective refractive index difference is dependent on the initial refractive indices and/or the refractive indices of the waveguide layer sequence. For example, by adjusting the initial refractive indices of the layers of the waveguide layer sequence, the effective refractive index difference and thus the coupling are adjusted.

According to at least one embodiment of the method, the threshold value corresponds to the effective refractive index difference, and the refractive indices of the waveguide layer sequence are chosen if the effective refractive index difference is at least 4.104, otherwise the coupling is again considered as a function of the adjusted refractive indices.

If the coupling is again considered as a function of the adjusted refractive indices, the refractive indices of the waveguide layer sequence are chosen in order to exceed an effective refractive index difference of at least 4·10⁻⁴. The loop of adjusting the refractive indices and considering the corresponding coupling is carried out as often as necessary such that the refractive index difference is at least 4·10⁻⁴.

According to at least one embodiment of the method, a polarization intensity ratio is dependent on the effective refractive index difference.

According to at least one embodiment of the method, the coupling of the TE mode and the TM mode is dependent on an extension of the TM mode in the second transverse direction. For example, the initial waveguide layer sequence is adjusted such that the TM mode extends as much as possible in the second transverse direction, i.e. the vertical direction. Advantageously, the overlap between the TE mode and the TM mode is reduced, leading to a reduced coupling of the TE mode and the TM mode. Exemplarily, due to the large extent of the TM mode in the second transverse direction, the mismatch of the first effective refractive index and the second effective refractive index is advantageously enlarged. Further, since the overlap between the TE mode and the TM mode is reduced, the coupling constant κ in the mode coupling equations is advantageously decreased.

According to at least one embodiment of the method, the coupling of the TE mode and the TM mode is dependent on a length of the waveguide layer sequence. For example, if the length of the waveguide layer sequence is less than 500 μm, the effect of the mismatch of the first effective refractive index and the second effective refractive index is negligible. For longer waveguides the effective refractive index mismatch becomes significant for the polarization purity.

According to at least one embodiment of the method, the coupling of the TE mode and the TM mode is dependent on a thickness of each of the layers of the waveguide layer sequence. For example, during the choosing of the refractive indices of the waveguide layer sequence, the thicknesses of the layers of the waveguide layer sequence are also adjusted depending on the threshold value of the coupling.

For example, the thicknesses and the materials of the waveguide layer sequence are chosen in order to decrease a coupling strength between the TE mode and the TM mode, in particular between the TE ground mode and the TM ground mode, to be below the threshold value.

Exemplarily during the adjustment of the initial refractive indices, sublayers can be added and/or omitted to the waveguide layer sequence. Further, during the adjustment of the initial refractive indices, further sublayers can be added and/or omitted to the first cladding layer and/or the second cladding layer.

In addition, a method producing a radiation-emitting laser diode is provided.

According to at least one embodiment of the method for producing a radiation-emitting laser diode, a waveguide layer sequence is produced having the refractive indices chosen by the method for choosing the refractive indices of a waveguide layer sequence for a radiation-emitting laser diode described herein before. Therefore, all features disclosed in connection with the method for choosing the refractive indices of a waveguide layer sequence are also disclosed in connection with the method for producing a radiation-emitting laser diode and vice versa.

For example, the waveguide layer sequence is produced by an epitaxial process. In particular, the active region, the first waveguide layer and the second waveguide layer are produced having a refractive index which is chosen by the method for choosing the refractive indices of a waveguide layer sequence described herein before.

### BRIEF DESCRIPTION OF THE DRAWINGS

The radiation-emitting laser diode and the method for choosing refractive indices of the waveguide layer sequence for the radiation-emitting laser diode described herein are explained in greater detail below with reference to exemplary embodiments and the associated figures.

FIG. 1 shows a schematic representation of a radiation-emitting laser diode according to an exemplary embodiment;

FIGS. 2 and 3 each exemplarily show a spatial profile of a real part of the refractive index of layers of a radiation-emitting laser diode according to an exemplary embodiment; and

FIG. 4 exemplarily shows a measurement of the polarization intensity ratio and the calculated effective refractive index difference of different radiation-emitting laser diodes.

Identical, similar or identically acting elements are provided with the same reference signs in the figures. The figures and the size ratios of the elements represented in the figures among one another are not drawn to scale. Rather, individual elements, in particular layer thicknesses, can be represented exaggeratedly large for better illustration and/or for better comprehension.

### DETAILED DESCRIPTION OF ILLUSTRATIVE EMBODIMENTS

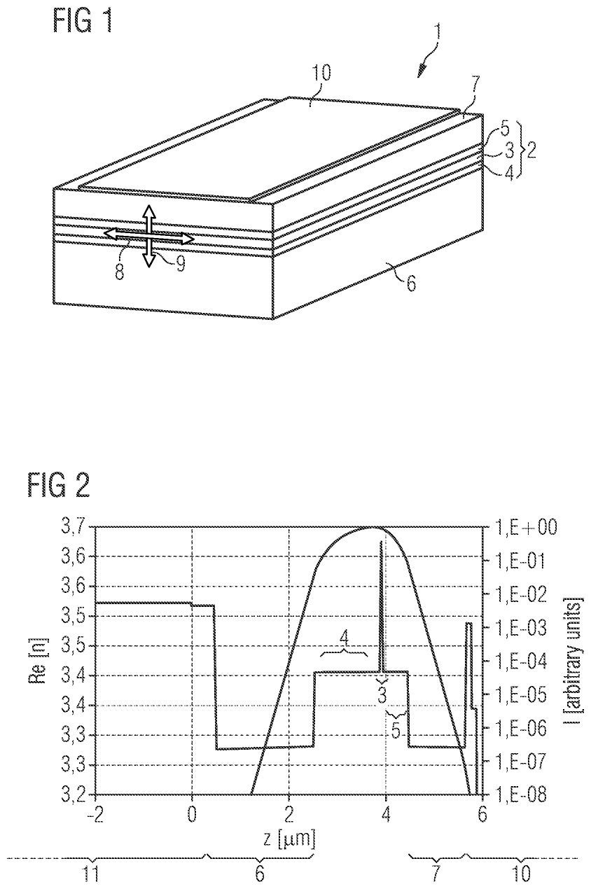

The radiation-emitting laser diode 1 according to the exemplary embodiment of FIG. 1 comprises a waveguide layer sequence 2. The waveguide layer sequence 2 comprises an active region 3 configured to generate electromagnetic radiation. Furthermore, the waveguide layer sequence 2 comprises a first waveguide layer 4 of a first doping type, and a second waveguide layer 5 of a second doping type. The active region 3 is arranged between the first waveguide layer 4 and the second waveguide layer 5.

A first cladding layer 6 of the first doping type is arranged on the waveguide layer sequence 2 on a first main surface. The first main surface is formed by an outer surface facing away from the active region of the first waveguide layer 4. Furthermore, a second cladding layer 7 of the second doping type is arranged on the waveguide layer sequence 2 on a second main surface. The second main surface is formed by an outer surface facing away from the active region of the second waveguide layer 5. The first cladding layer 6 is in direct contact to the first waveguide layer 4 and the second cladding layer 7 is in direct contact to the second waveguide layer 5.

Furthermore, a metallic contact layer 10 is arranged on the second cladding layer 7 in an electrically and thermally conductive manner. The metallic contact layer 10 is in direct contact to the second cladding.

The first cladding layer 6, the first waveguide layer 4, the active region 3, the second waveguide layer 5, the second cladding layer 7 and the metallic contact layer 10 are arranged above one another in the order indicated.

The first doping type is different from the second doping type. For example, the first doping type is n-type and thus, the first cladding layer 6 and the first waveguide layer 4 are at least partially n-doped. It is possible that parts of the waveguide layer 4 are undoped and/or comprise p-type dopants. Since the doping types are different, the second doping type is p-type and thus, the second cladding layer 7 and the second waveguide layer 5 are p-doped.

The layers of the wave guide layer sequence 2, the first cladding layer 6 and the second cladding layer 7 each extend parallel to a main extension plane. Furthermore, the layers of the wave guide layer sequence 2, the first cladding layer 6 and the second cladding layer 7 each extend in a main extension direction.

During operation of the radiation-emitting laser diode 1, the electromagnetic radiation generated in the active region 3 is predominantly emitted as electromagnetic radiation into the waveguide layer sequence 2.

Due to different boundary conditions within the waveguide layer sequence 2, the electromagnetic radiation comprises two transverse modes, namely a transverse electric, TE, mode and a transverse magnetic, TM, mode. An electric field of the TE mode oscillates along a first transverse direction 8 and an electric field of the TM mode oscillates along a second transverse direction 9. The first transverse direction 8 and the second transverse direction 9 are aligned in a plane being perpendicular to the main extension direction. The main extension direction is parallel to a propagation direction of the electromagnetic radiation. Furthermore, the first transverse direction 8 and the second transverse direction 9 are aligned perpendicular to one another within the plane being perpendicular to the main extension direction.

Due to polarization dependent boundary conditions between adjacent layers of the waveguide layer sequence 2, the first cladding layer 6 and the second cladding layer 7, the TE mode and the TM mode feature different effective refractive indices. Also, the TE mode has a different overlap with the waveguide layer sequence 2, the first cladding layer 6 and the second cladding layer 7 than the TM mode.

Due to the different boundary conditions, the TE mode features a first effective refractive index for oscillation of its electrical field along the first transverse direction and the TM mode features a second effective refractive index for oscillation of its electrical field along the second transverse direction.

The refractive indices of the waveguide layer sequence 2, the first cladding layer 6 and the second cladding layer 7 are configured in such a way that an effective refractive index difference of the first effective refractive index and the second effective refractive index is at least 4·10⁻⁴, in particular at least 5·10⁻⁴. Having such an effective refractive index difference, a polarization intensity ratio of the electromagnetic radiation emitted from the radiation-emitting laser diode 1 is at least 90%, in particular at least 93%.

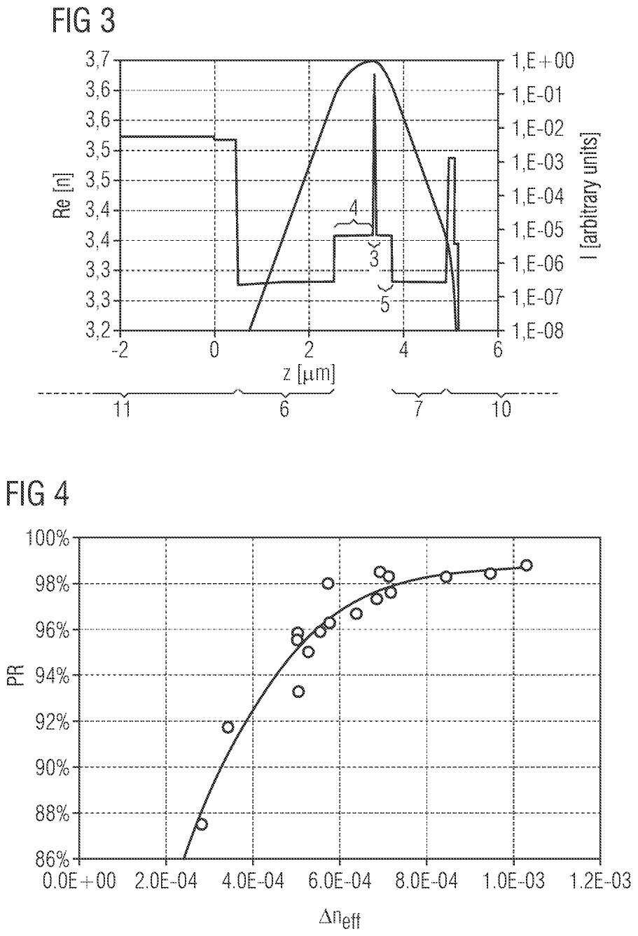

The diagrams according to FIGS. 2 and 3 show on the left y-axis a real part of a refractive index Re(n) of the layers of the radiation-emitting laser diode 1. On the right y-axis a normalized intensity I in arbitrary units of the TE mode and the TM mode is shown. On the x-axis a position z in μm in vertical direction, i.e. a stacking direction of the layers of the radiation-emitting laser diode 1, is shown.

According to FIG. 2, the radiation-emitting laser diode 1 within this exemplary embodiment of FIG. 2 comprises, in addition to the radiation-emitting laser diode 1 of FIG. 1, a substrate 11. The substrate 11 is arranged on the first cladding layer 6. The first cladding layer 6 has a thickness of about 2 μm. The first waveguide layer 4 has a thickness of about 1.3 μm and the second waveguide layer 5 has a thickness of about 500 nm. The active region 3 sandwiched between the first waveguide layer 4 and the second waveguide layer 5 has a thickness of about 100 nm. The second cladding layer 7 has a thickness of about 1.2 μm.

Within such a radiation-emitting laser diode 1, the first effective refractive index, in particular the real part of the first effective refractive index, for the TE mode is 3.40258 and the second effective refractive index, in particular the real part of the second effective refractive index, for the TM mode is 3.40215. Therefore, the effective refractive index difference is 3.30·10⁻⁴.

According to FIG. 3, the first cladding layer 6 has a thickness of about 2.1 μm. The first waveguide layer 4 has a thickness of about 750 nm and the second waveguide layer 5 has a thickness of about 250 nm. The active region 3 sandwiched between the first waveguide layer 4 and the second waveguide layer 5 has a thickness of about 100 nm. The second cladding layer 7 has a thickness of about 1.1 μm.

Within a radiation-emitting laser diode 1 according to FIG. 3, the first effective refractive index, in particular the real part of the first effective refractive index, for the TE mode is 3.35245 and the second effective refractive index, in particular the real part of the second effective refractive index, for the TM mode is 3.35149. Therefore, the effective refractive index difference is 9.6·10⁻⁴.

In the diagram according to FIG. 4, a polarization intensity ratio PR is depicted in percent on the y-axis. On the x-axis, an effective refractive index difference Δn_{eff} of a first effective refractive index of a TE mode and a second effective refractive index of a TM mode of different radiation-emitting laser diodes 1 is shown. The radiation-emitting laser diodes 1 are mounted via a metallic contact layer 10 to a carrier.

The polarization intensity ratio of each radiation-emitting laser diode 1 is measured via an optical experiment.

A coupling of the TE mode and the TM mode is dependent on an effective refractive index difference. In particular, by reducing the coupling of the TE mode and the TM mode, the polarization intensity ratio can be increased.

If a polarization intensity ratio of at least 96% is desired, an effective refractive index difference of at least 6.7·10⁻⁴ has to be achieved. This can be achieved by designing refractive indices of a waveguide layer sequence 2 including the first cladding layer 6 and the second cladding layer 7 for a radiation-emitting laser diode 1 as a function of the coupling of the TE mode and the TM mode.

Initially, within a method for choosing such refractive indices, initial refractive indices are provided for a waveguide layer sequence 2 of a radiation-emitting laser diode 1. The initial refractive indices are represented, for example, by the refractive indices of the layers of a radiation-emitting laser diode 1.

In a next step the coupling of the TE mode and the TM mode is considered. For example, the refractive index difference is determined by a simulation, e.g., by solving the Eigenvalue equations of the wave guide layer sequence. If the coupling is below a threshold value, i.e. if the effective refractive index difference is below 4·10⁻⁴, the refractive indices of the layers of the radiation-emitting laser diode 1 are adjusted.

Subsequently, the coupling of the radiation-emitting laser diode 1 with the adjusted refractive indices is chosen accordingly.

The features and exemplary examples described in connection with the Figures can be combined with one another according to further exemplary examples, even if not all combinations are explicitly described. Furthermore, the exemplary examples described in connection with the Figures can alternatively or additionally have further features as described in the general part of the description.

The invention is not limited to the exemplary examples by the description based on the exemplary examples. Rather, the invention comprises any new feature as well as any combination of features, which includes in particular any combination of features in the claims, even if this feature or combination itself is not explicitly stated in the claims or exemplary examples.

1-14. (canceled)

15. A radiation-emitting laser diode comprising:
a waveguide layer sequence comprising:
an active region configured to generate electromagnetic radiation with a preferred polarization direction;
a first waveguide layer of a first doping type; and
a second waveguide layer of a second doping type,
wherein the active region is arranged between the first waveguide layer and the second waveguide layer,
wherein refractive indices of the waveguide layer sequence form a first effective refractive index for a transverse electric (TE) mode with its electric field oscillating in a first transverse direction and a second effective refractive index for a transverse magnetic (TM) mode with its electric field oscillating in a second transverse direction, and
wherein an effective refractive index difference of the first effective refractive index and the second effective refractive index is at least 4·10⁻⁴.

16. The radiation-emitting laser diode according to claim 15,
wherein refractive indices of the active region, the first waveguide layer and the second waveguide layer differ from one another, and/or
wherein thicknesses of the active region, the first waveguide layer and the second waveguide layer differ from one another.

17. The radiation-emitting laser diode according to claim 15, wherein a length of the waveguide layer sequence is at least 500 μm and at most 6 mm.

18. The radiation-emitting laser diode according to claim 15, further comprising:
a first cladding layer of the first doping type arranged on the waveguide layer sequence on a first main surface and
a second cladding layer of the second doping type arranged on the waveguide layer sequence on a second main surface.

19. The radiation-emitting laser diode according to claim 18, further comprising a metallic contact layer arranged on the second cladding layer in an electrically and thermally conductive manner.

20. The radiation-emitting laser diode according to claim 18, further comprising a substrate arranged on the first cladding layer, wherein the first cladding layer comprises a mode spoiler.

21. A method for choosing refractive indices of a waveguide layer sequence for a radiation-emitting laser diode, the method comprising:
providing initial refractive indices for the waveguide layer sequence comprising an active region for generating electromagnetic radiation, a first waveguide layer of a first doping type, and a second waveguide layer of a second doping type;
considering a coupling of a transverse electric (TE) mode in a first transverse direction and a transverse magnetic (TM) mode in a second transverse direction in the waveguide layer sequence as a function of the initial refractive indices; and
choosing the refractive indices of the waveguide layer sequence by adjusting the initial refractive indices depending on a threshold value of the coupling.

22. The method according to claim 21,
wherein the coupling is dependent on an effective refractive index difference of a first effective refractive index for the TE mode and a second effective refractive index for the TM mode, and
wherein an effective refractive index is dependent on the initial refractive indices and/or the refractive indices of the waveguide layer sequence.

23. The method according to claim 22,
wherein the threshold value corresponds to the effective refractive index difference, and
wherein the refractive indices of the waveguide layer sequence are determined when the effective refractive index difference is at least 4·10⁻⁴, otherwise the coupling is again determined as a function of the adjusted refractive indices.

24. The method according to claim 21, wherein a polarization intensity ratio is dependent on an effective refractive index difference.

25. The method according to claim 21, wherein the coupling of the TE mode and the TM mode is dependent on an extension of the TM mode in the second transverse direction.

26. The method according to claim 21, wherein the coupling of the TE mode and the TM mode is dependent on a length of the waveguide layer sequence.

27. The method according to claim 21, wherein the coupling of the TE mode and the TM mode is dependent on a thickness of each of the layers of the waveguide layer sequence.

28. A method for producing the radiation-emitting laser diode, wherein the method for producing the radiation-emitting laser diode comprises producing the waveguide layer sequence having the refractive indices chosen by the method according to claim 21.

29. A radiation-emitting laser diode comprising:
a waveguide layer sequence comprising:
an active region configured to generate electromagnetic radiation of a preferred polarization direction;
a first waveguide layer of a first doping type; and
a second waveguide layer of a second doping type,
wherein the active region is arranged between the first waveguide layer and the second waveguide layer,
wherein refractive indices of the waveguide layer sequence form a first effective refractive index for a transverse electric (TE) mode with its electric field oscillating in a first transverse direction and a second effective refractive index for a transverse magnetic (TM) mode with its electric field oscillating in a second transverse direction, and
wherein an effective refractive index difference of the first effective refractive index and the second effective refractive index is at least 4·10⁻⁴ and at most 5·10⁻³.
